(19) United States
(12) Patent Application Publication
(10) Pub. No.: US 2006/0115746 A1
(43) Pub. Date: Jun. 1, 2006

(54) Focus monitoring masks having multiple phase shifter units and methods for fabricating the same

(76) Inventors: Sung-Won Choi, Gyeonggi-do (KR); Suk-joo Lee, Gyeonggi-do (KR); Ho-chul Kim, Seoul (KR); Han-ku Cho, Gyeonggi-do (KR); Sang-gyun Woo, Gyeonggi-do (KR)

Correspondence Address: MYERS BIGEL SIBLEY & SAJOVEC, PO BOX 37428, RALEIGH, NC, 27627, US

(21) Appl. No.: 11/280,606

(22) Filed: Nov. 16, 2005

(30) Foreign Application Priority Data
Nov. 30, 2004 (KR) 2004-99055

(51) Int. Cl. G03C 5/00; G03F 1/00

(52) U.S. Cl. 430/5; 430/322; 430/323; 430/324; 430/394

(57) ABSTRACT

A focus monitoring mask includes a transparent substrate, e.g., a quartz layer. A light blocking film, e.g., a chromium-containing film, is disposed on the transparent substrate and has an opening therein. A transparent unit is disposed in a portion of the substrate exposed by the opening. The transparent unit includes a first phase shifter, a second phase shifter and a third phase shifter arranged adjacently in order of amount of phase shift. The second phase shifter is configured to provide an about 180° phase difference with respect to the first phase shifter. The third phase shifter is configured to provide a phase difference other than about 0° and about 180° with respect to the first phase shifter. The transparent unit may further include a fourth phase shifter having a fourth phase difference with respect to the first phase shifter that differs from about 0°, about 180° and the phase difference provided by the third phase shifter.

### CROSS-REFERENCE TO RELATED PATENT APPLICATIONS

This application claims the priority of Korean Patent Application No. 10-2004-0099055, filed on Nov. 30, 2004, in the Korean Intellectual Property Office, the disclosure of which is hereby incorporated by reference herein in its entirety.

### BACKGROUND OF THE INVENTION

The present invention relates to semiconductor device fabrication and, more particularly, to focus monitoring masks and methods of fabrication therefor.

Typical techniques for manufacturing semiconductor devices include a plurality of photolithography processes and etching processes for forming patterns on a semiconductor substrate. A typical photolithography process involves transferring a pattern formed on a photo mask to a semiconductor substrate using a photoresist. A typical photolithography process includes coating a photoresist on a semiconductor substrate, exposing the photoresist using a photo mask, developing the exposed photoresist using a developing solution to form an etch mask, etching a target etching layer on the substrate using the etch mask, and removing the etch mask.

As semiconductor devices have become more highly integrated, a critical dimension (CD) has become smaller. Generally, to reduce a critical dimension, a numerical aperture (NA) of the exposure equipment must be larger, a wavelength of light must be smaller and/or a depth of focus must be narrower. Accordingly, line width control of a pattern may be very complicated, as critical dimension may be strongly influenced by factors such as variation of a photoresist's thickness, unbalanced bake, interference of thin films and lack of lens flatness.

The factors influencing a critical dimension may cause variation in focus of light passed through the photo mask, which may influence line width control of the pattern. Accordingly, it is generally desirable that a focus window of each process be improved and/or variation of focus decreased to finely control line width of the pattern. Therefore, it may be desirable to accurately measure variation of focus during fabrication of a semiconductor device.

Determination of optical focus may be an indefinite and time-consuming process. A pattern exposure process using a focus set having a matrix structure may be used. A result of exposure of such a set may be inspected using an electron microscope to determine an optical image produced by the exposure. The focus may be determined from the optical image.

When various patterns are formed on a wafer including various thin films, line width control of the pattern may get more complicated and a target line width may not be achieved. Furthermore, it may be difficult to determine how much the focus is shifted for implementing the target pattern line width.

Many techniques have been developed for monitoring movement of pattern according to a focus. A conventional technique for monitoring pattern movement involves use of a monitoring mask. However, the line width of patterns has been further reduced by increasing the degree of integration of semiconductor devices and, consequently, variation of pattern movement due to focus has also decreased. Therefore, it may be difficult to obtain reliable results in monitoring movement of a pattern because of the small variation value of pattern movement, i.e., increased sensitivity.

### SUMMARY OF THE INVENTION

In some embodiments of the present invention, a focus monitoring mask includes a transparent substrate, e.g., a quartz layer. A light blocking film, e.g., a chromium-containing film, is disposed on the transparent substrate and has an opening therein. A transparent unit is disposed in a portion of the substrate exposed by the opening. The transparent unit includes a first phase shifter, a second phase shifter and a third phase shifter arranged adjacently in order of amount of phase shift. The second phase shifter is configured to provide an about 180° phase difference with respect to the first phase shifter. The third phase shifter is configured to provide a phase difference other than about 0° and about 180° with respect to the first phase shifter. For example, the third phase shifter may be configured to provide a phase difference of about 90° or about 270° with respect to the first phase shifter. The transparent unit may further include a fourth phase shifter having a fourth phase difference with respect to the first phase shifter that differs from about 0°, about 180° and the phase difference provided by the third phase shifter. For example, the fourth phase shifter may be configured to provide a phase difference of about 270° with respect to the first phase shifter and the third phase shifter may be configured to provide a phase difference of about 90° with respect to the first phase shifter.

The first phase shifter may have substantially the same thickness as a portion of the transparent substrate covered by the light blocking layer. At least some of the phase shifters may include respective recessed portions of the transparent substrate having respective different thicknesses. Phase shifters having greater phase differences may have lesser thicknesses. A width of the phase shifters may be based on a width of a pupil plane of exposure equipment used therewith. The width of the phase shifters may be reduced as the width of a pupil plane of equipment used therewith becomes wider.

In some method embodiments, a light blocking film is formed on a transparent substrate. Respective portions of the light blocking film are removed to expose spaced apart first and second regions of the transparent substrate. The exposed first and second regions of the transparent substrate are etched a first depth. A portion of the light blocking film between the first and second regions of the transparent substrate is removed to expose a third region of the transparent substrate. The second and third regions of the transparent substrate are etched a second depth, and a portion of the light blocking film adjacent the first region is removed to expose a fourth region of the transparent substrate. In this manner, respective first, second, third and fourth phase shifters are formed at respective ones of the fourth, first, third and second regions of the transparent substrate.

The first depth may be a depth sufficient to provide a phase shift of about 90° with respect to the first phase shifter, and the second depth may be a depth sufficient to provide a phase shift of about 180° with respect to the first phase shifter. The second depth may be about twice the first depth.

Removing respective portions of the light blocking film to expose spaced apart first and second regions of the transparent substrate may include forming a first photoresist layer having first and second openings therein exposing the light blocking film at the first and second regions of the transparent substrate, and etching the light blocking film using the first photoresist layer as an etch mask. Etching the exposed first and second regions of the transparent substrate a first depth may include etching the transparent substrate using the first photoresist layer as an etch mask. Removing a portion of the light blocking film between the first and second regions of the transparent substrate to expose a third region of the transparent substrate may include forming a second photoresist layer having an opening therein exposing the light blocking film at the third region of the transparent substrate and etching the light blocking film at the third region using the second photoresist layer as an etch mask. The opening in the second photoresist layer may also expose the second region of the transparent substrate, and etching the second and third regions of the transparent substrate a second depth may include etching the second and third regions of the transparent substrate using the second photoresist layer as an etch mask.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram of a focus monitoring mask in accordance with some embodiments of the present invention;

FIG. 2 is a cross sectional view of the focus monitoring mask in FIG. 1 taken along a line A-A′;

FIG. 3 illustrates focus monitoring operations in accordance with further embodiments of the present invention;

FIG. 4 is a graph of simulation results illustrating sensitivity of a focus monitoring mask in accordance with some embodiments of the present invention; and

FIGS. 5-12 are diagrams illustrating exemplary operations for fabricating a focus monitoring mask in accordance with further embodiments of the present invention.

### DETAILED DESCRIPTION OF EXEMPLARY EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

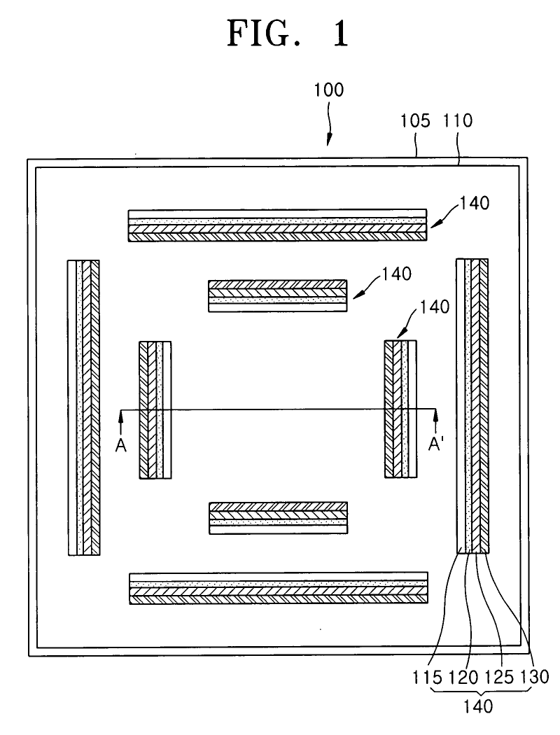

FIG. 1 is a diagram of a focus monitoring mask 100 in accordance with some embodiments of the present invention. The focus monitoring mask 100 includes a light blocking film 110 and a plurality of transparent units 140. The light blocking film 110 is formed on a transparent substrate 105 and the transparent units 140 are formed in the transparent substrate 105. Quartz may be used for forming the transparent substrate 105 and chromium (Cr) may be used to form the light blocking film 110.

The transparent units 140 may include four phase shifters 115, 120, 125, 130, each of which has a unique phase. The transparent units 140 include phase shifters having about 0° and about 180° phase differences among the four phase shifters 115, 120, 125 and 130 to increase sensitivity for focus monitoring. For example, the first phase shifter 115 may have an about 0° phase difference with respect to the transparent substrate 105, i.e., the first phase shifter 115 may have a phase substantially identical to a phase of the transparent substrate 105. The second phase shifter 120 may have an about 90° phase difference with respect to the transparent substrate 105, the third phase shifter 125 may have an about 180° phase difference with respect to the transparent substrate 105, and the fourth phase shifter 130 may have an about 270° phase difference with respect to the transparent substrate 105.

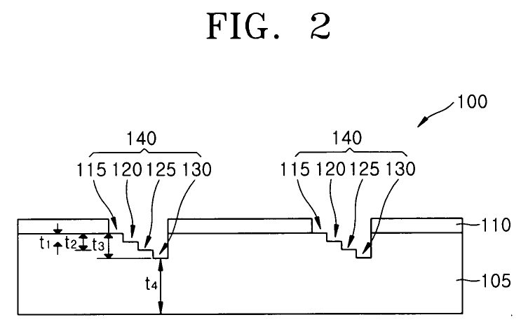

FIG. 2 is a cross-sectional view of the focus monitoring mask 100 of FIG. 1 taken along a line A-A′. The phase shifters 115, 120, 125, and 130 of the transparent units 140 include respective portions of the transparent substrate 105 having respective different thicknesses. The phase difference between the phase shifters and the (full thickness) transparent substrate 105 increases with decreased thickness of the phase shifter, e.g., the fourth phase shifter 130 is thinner than the first phase shifter 115. The first phase shifter 115 includes a non-recessed portion of the transparent substrate 105 having a first thickness (t4+t3). The second phase shifter 120 is recessed a first depth (t1) from a surface of the transparent substrate 105 and has a second thickness (t4+t3−t1). The third phase shifter 125 is recessed a second depth (t2) from the surface of the transparent substrate 105 and has a third thickness (t4+t3−t2), which is less than that of the second phase shifter 120. The fourth phase shifter 130 is recessed a third depth (t3) from the surface of the transparent substrate 105 and has a fourth thickness (t4), which is less than that of the third phase shifter 125.

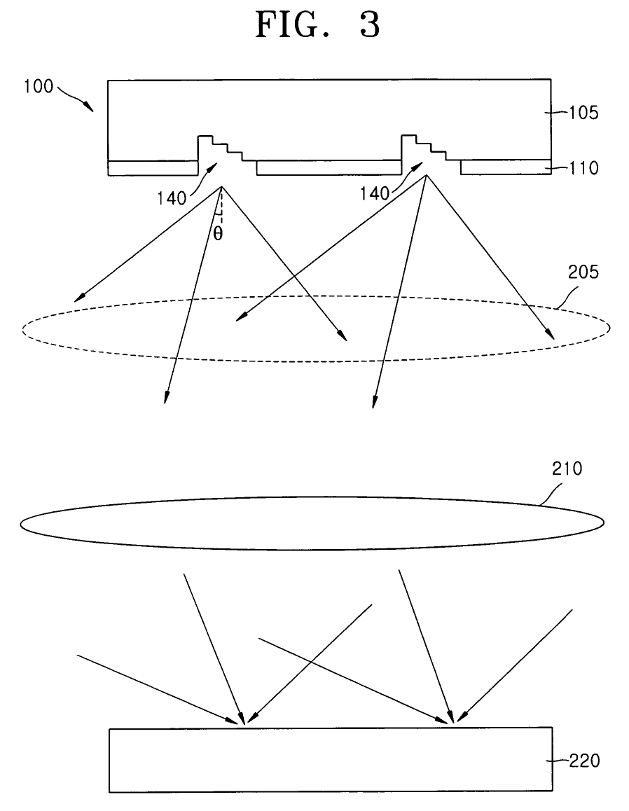

FIG. 3 is a view illustrating exemplary focus monitoring operations using the focus monitoring mask 100 of FIG. 1 in accordance with further embodiments of the present invention. Light passed through the transparent units 140 is projected to a semiconductor substrate 220 through a projection lens 210. The light passed through the transparent units 140 is asymmetrically projected. The light passed through the transparent unit 140 is tilted as much as a declination angle (θ). The light is tilted because the transparent unit 140 includes a plurality of phase shifters 115, 120, 125 and 130. In particular, the declination angle increases by including the first phase shifter 115 having an about 0° phase shift and the third phase shifter 125 having an about 180° phase shift.

However, a target declination angle may not be provided by the first and the third phase shifters. Accordingly, the second and fourth phase shifters 120, 130 may be included to achieve the target declination angle (θ). The target declination angle (θ) may be provided by including one of the third or the fourth phase shifters 125, 130 with the first and second phase shifters 115, 120.

As the declination angle (θ) of the light passed through the transparent unit 140 increases, movement of a pattern formed on the semiconductor substrate 220 according to each focus becomes wider, i.e., the sensitivity increases. The sensitivity represents a movement of a predetermined pattern. If the sensitivity increases, control of focus may be reliably performed when the critical dimension CD of the pattern is out of specification.

As a width of each phase shifters 115, 120, 125 and 130 decreases, the declination angle (θ) increases. However, if the phase shifters 115, 120, 125 and 130 are too narrow, the light passed through the transparent unit 140 may deviate from a virtual pupil plane 205 of exposure equipment. Therefore, the width of each phase shifter may be controlled based on a width of the pupil pane 205 of the exposure equipment. In particular, it may be desirable to form the phase shifters to have the narrowest allowable width in a range of the pupil plane 205 for in order to achieve high sensitivity.

FIG. 4 is a graph showing a result of a simulation of sensitivity of a focus monitoring mask in accordance with some embodiments of the present invention. As shown in FIG. 4, the focus monitoring mask may provide about a 0.36 sensitivity. Accordingly, the focus monitoring mask may provide higher sensitivity than conventional masks that have about a 0.2 sensitivity. Therefore, reliable focus control may be achieved for forming patterns for manufacturing of a semiconductor device.

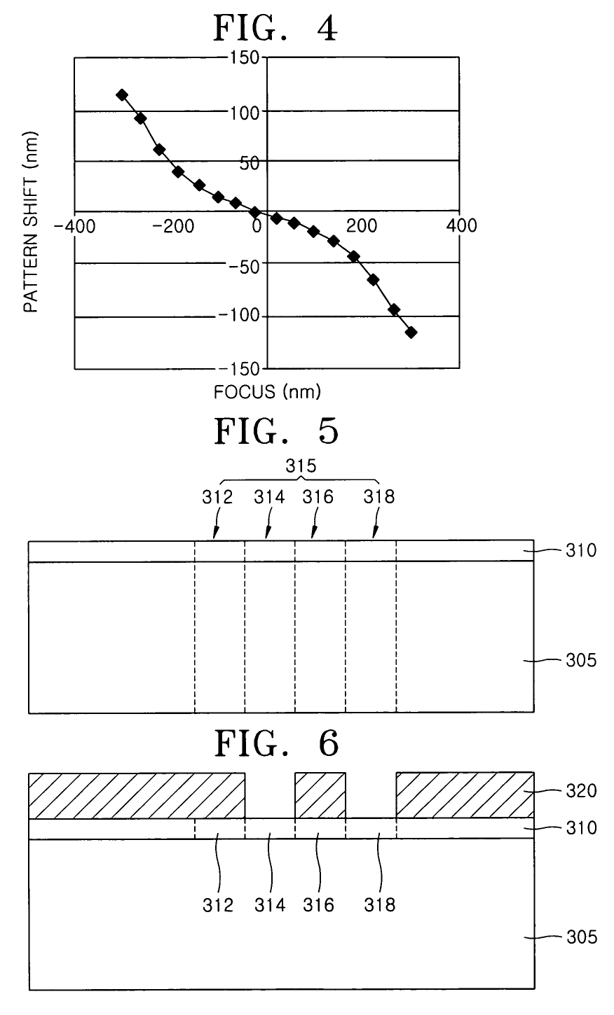

FIGS. 5 through 12 are diagrams of operations for fabricating a focus monitoring mask in accordance with some embodiments of the present invention. Referring to FIG. 5, a light blocking film 310 is formed on a transparent substrate 305. The light blocking film 310 may include chromium (Cr). A transparent unit region 315, including phase shifter regions 312, 314, 316, 318, is defined. Portions of the light blocking film 310 at the transparent unit region 315 are removed and phase shifters formed in the transparent unit region 315.

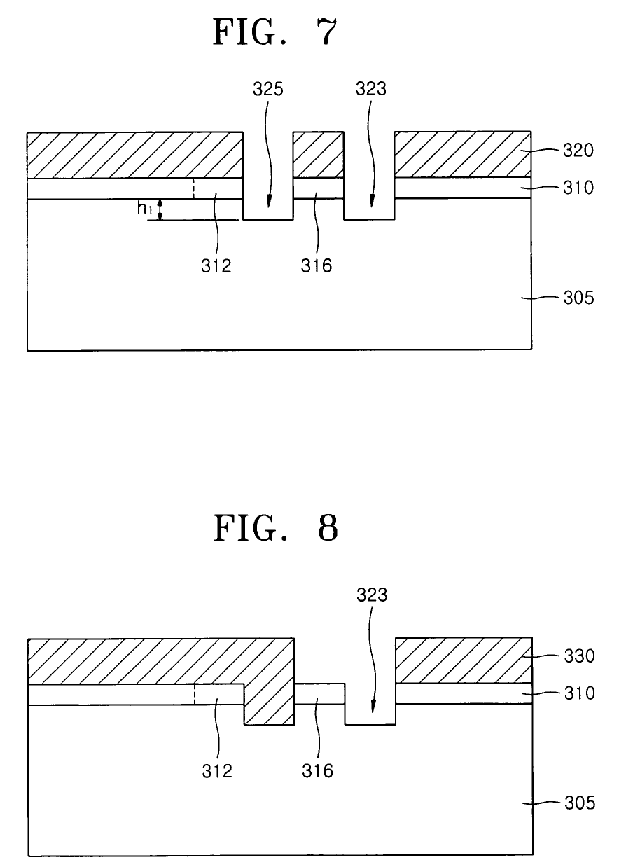

Referring to FIG. 6, a first photoresist layer 320 is formed, exposing the light blocking film 310 at a first region 314 and a second region 318. The first photoresist layer 320 may be formed using a spin coating method. Referring to FIG. 7, portions of the light blocking film 310 at the first region 314 and the second region 318 are removed using the first photoresist layer 320 as an etch mask using, for example, an anisotropic etching process. Portions of the transparent substrate 305 at the first region 314 and the second region 318 are etched using the first photoresist layer 320 as an etch mask to a first depth (h1), to forming a second phase shifter 325 and a preliminary fourth phase shifter 323. The first depth (h1) is a depth that provides the second phase shifter 325 with a 90° phase difference with respect to the transparent substrate 305. After etching the transparent substrate 305 at the first region 314 and the second region 318, the first photoresist layer 320 is removed.

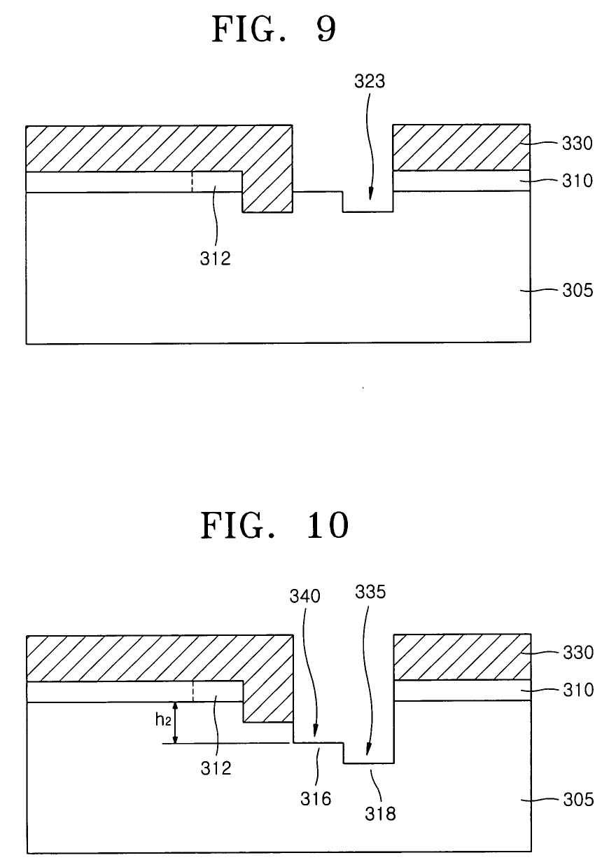

Referring to FIG. 8, a second photoresist layer 330 is formed, exposing the light blocking film 310 at a third region 316 and the recess in the transparent substrate 305 at the second region 318. The portion of the light blocking film 310 at the third region 316 is removed using the second photoresist layer 330 as an etch mask as shown in FIG.9. The light blocking film 310 may be selectively etched using an etching selectivity of the light blocking film 310 with respect to the transparent substrate 305.

Referring to FIG. 10, the transparent substrate 305 at the third region 316 and the second region 318 is etched to a second depth (h2) using the second photoresist layer 330 as an etch mask to form a third phase shifter 340 and a fourth phase shifter 335. The second depth h2 is a depth sufficient to provide an about 180° phase difference for the third phase shifter 340 with respect to the transparent substrate 305. The second depth h2 may be two times greater than the first depth h1 of FIG. 7.

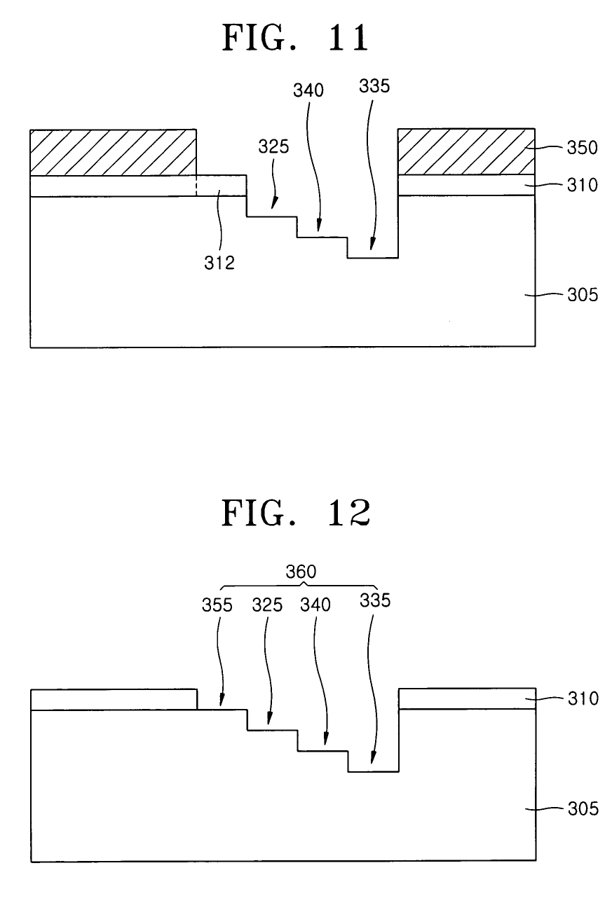

Referring to FIG. 11, a third photoresist layer 350 is formed, exposing the light blocking film 310 at a fourth region 312. During formation of the third photoresist layer 350, the second phase shifter 325, the third phase shifter 340 and the fourth phase shifter 335 may be exposed as shown in FIG. 11. Referring to FIG. 12, the light blocking film 310 at the fourth region 312 is etched using the third photoresist layer 350 as an etch mask. The transparent substrate 305 may not be significantly etched because of an etching selectivity of the light blocking film 310 with respect to the transparent substrate 305. The removal of the light blocking film 310 at the fourth region 312 forms the first phase shifter 355. The first phase shifter 355 has 0° phase difference with respect to the transparent substrate 305.

A transparent unit 360 including the first phase shifter 355, the second phase shifter 325, the third phase shifter 340 and the fourth phase shifter 335 are thus formed. The first phase shifter 355 has an about (approximately) 0° phase difference with respect to the transparent substrate 305. The second phase shifter 325 has an about 90° phase difference and the third shifter 340 has an about 180° phase difference with respect to the transparent substrate 305. The fourth phase shifter 335 has an about 270° phase difference with respect to the transparent substrate 305. As the second, the third and the fourth phase shifters 325, 340 and 335 may be formed using relatively few masking and etching operations, the patterning process may be simplified and the focus monitoring mask may be economically fabricated.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A focus monitoring mask, comprising:
a transparent substrate;
a light blocking film on the transparent substrate and having an opening therein;
a transparent unit in a portion of the substrate exposed by the opening, the transparent unit comprising a first phase shifter, a second phase shifter and a third phase shifter arranged adjacently in order of amount of phase shift, the second phase shifter configured to provide an about 180° phase difference with respect to the first phase shifter and the third phase shifter configured to provide a phase difference other than about 0° and about 180° with respect to the first phase shifter.

2. The focus monitoring mask of claim 1, wherein the first phase shifter has substantially the same thickness as a portion of the transparent substrate covered by the light blocking layer.

3. The focus monitoring mask of claim 1, wherein the third phase shifter is configured to provide a phase difference of about 90° or about 270° with respect to the first phase shifter

4. The focus monitoring mask of claim 1, wherein the transparent unit further includes a fourth phase shifter having a fourth phase difference with respect to the first phase shifter that differs from about 0°, about 180° and the phase difference provided by the third phase shifter.

5. The focus monitoring mask of claim 4, wherein the fourth phase shifter is configured to provide a phase difference of about 270° with respect to the first phase shifter and the third phase shifter is configured to provide a phase difference of about 90° with respect to the first phase shifter.

6. The focus monitoring mask of claim 1, wherein at least some of the phase shifters comprise respective recessed portions of the transparent substrate having respective thicknesses.

7. The focus monitoring mask of claim 6, wherein phase shifters having the greater phase differences have lesser thicknesses.

8. The focus monitoring mask of claim 1, wherein a width of the phase shifters is based on a width of a pupil plane of exposure equipment used therewith.

9. The focus monitoring mask of claim 8, wherein the width of the phase shifters become narrower as the width of a pupil pane of exposure equipment becomes wider.

10. The focus monitoring mask of claim 1, wherein the light blocking film comprises chromium.

11. The focus monitoring mask of claim 1, wherein the transparent substrate comprises a quartz layer.

12. A method for fabricating a focus monitoring mask, comprising:
forming a light blocking film on a transparent substrate;
removing respective portions of the light blocking film to expose spaced apart first and second regions of the transparent substrate;
etching the exposed first and second regions of the transparent substrate a first depth;
removing a portion of the light blocking film between the first and second regions of the transparent substrate to expose a third region of the transparent substrate;
etching the second and third regions of the transparent substrate a second depth; and
removing a portion of the light blocking film adjacent the first region to expose a fourth region of the transparent substrate,
thereby forming respective first, second, third and fourth phase shifters at respective ones of the fourth, first, third and second regions of the transparent substrate.

13. The method of claim 12, wherein the first depth is a depth sufficient to provide a phase shift of about 90° with respect to the first phase shifter.

14. The method of claim 13, wherein the second depth is a depth sufficient to provide a phase shift of about 180° with respect to the first phase shifter.

15. The method of claim 14, wherein the second depth is about twice the first depth.

16. The method of claim 12, wherein removing respective portions of the light blocking film to expose spaced apart first and second regions of the transparent substrate comprises:
forming a first photoresist layer having first and second openings therein exposing the light blocking film at the first and second regions of the transparent substrate; and
etching the light blocking film using the first photoresist layer as an etch mask.

17. The method of claim 16, wherein etching the exposed first and second regions of the transparent substrate a first depth comprises etching the transparent substrate using the first photoresist layer as an etch mask.

18. The method of claim 16, wherein removing a portion of the light blocking film between the first and second regions of the transparent substrate to expose a third region of the transparent substrate comprises:
forming a second photoresist layer having an opening therein exposing the light blocking film at the third region of the transparent substrate; and
etching the light blocking film at the third region using the second photoresist layer as an etch mask.

19. The method of claim 18, wherein the opening in the second photoresist layer also exposes the second region of the transparent substrate, and wherein etching the second and third regions of the transparent substrate a second depth comprises etching the second and third regions of the transparent substrate using the second photoresist layer as an etch mask.

20. The method of claim 12, wherein the light blocking film comprises chromium.
